(19) United States
(12) Patent Application Publication
(10) Pub. No.: US 2012/0262854 A1
(43) Pub. Date: Oct. 18, 2012

(54) Protective casing for a portable electronic apparatus

(76) Inventor: Paul-Henri Robert, Boulogne (FR)

(21) Appl. No.: 13/246,187

(22) Filed: Sep. 27, 2011

(30) Foreign Application Priority Data
Apr. 13, 2011 (FR) 11/01132

(51) Int. Cl. H05K 7/00

(52) U.S. Cl. 361/679.01

(57) ABSTRACT

This casing for protecting a portable electronic apparatus, of the tablet computer type, comprises a shell (2) delimiting a housing for accommodating the electronic apparatus.

This casing comprises a handle (4) articulated on the rear face of the shell between a folded-back position in which it is flattened against the shell and an active deployed position allowing the casing to be held.

The invention relates to accessories for items of portable electronic apparatus of the tablet computer type but relates in general to items of equipment of any other type of portable electronic apparatus, of the mobile telephone, geolocation apparatus, digital walkman, personal assistant, games console type, etc.

As is known, this type of apparatus, in particular tablet computers, comprises a casing in which all the electronics of the apparatus are housed and, on the facade, a display screen. In tablet computers, the display screen occupies the majority of the front face of the apparatus.

Equipment manufacturers offer accessories making it possible to add to the apparatus as it is marketed. Many types of accessories are available in order, notably, to protect the apparatus against impacts or scratches or to hold it in an upright position of use.

It has however been found that the handling of tablet computers can be awkward because, due to their relatively large dimensions, it is not possible to hold them effectively in only one hand without masking a portion of the screen.

The object of the invention is therefore to alleviate this drawback and to propose a casing for protecting a portable electronic apparatus, of the tablet computer type, comprising a shell delimiting a housing for accommodating the electronic apparatus.

This casing also comprises a handle articulated on a rear face of the shell between a folded-back position in which it is flattened against the shell and an active deployed position allowing the casing to be held.

For example, the handle is generally arch-shaped.

In one embodiment, the length of the arch is such that, in the fully deployed position, the handle extends beyond the perimeter of the shell.

The handle may comprise inserts made of non-slip material.

In one advantageous embodiment, it may be mounted on a pivoting support.

For example, the support comprises a recess for retaining the handle in the folded-back position.

The handle may also constitute a stand capable of supporting the apparatus in an inclined position of use.

According to yet another feature of the casing, the latter is associated with a base provided with a pedestal and with a housing for accommodating the deployed handle.

Other objects, features and advantages of the invention will appear on reading the following description given only as a non-limiting example and made with reference to the appended drawings in which:

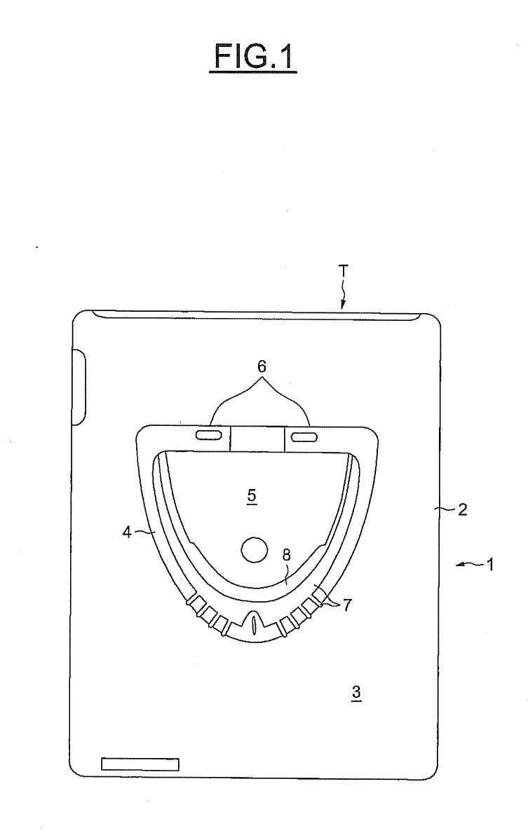

FIG. 1 is a rear view of a protective casing according to the invention;

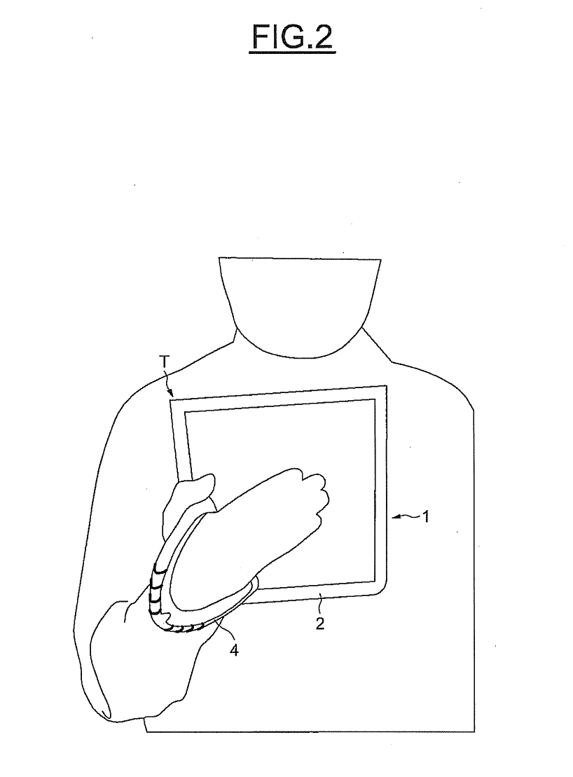

FIG. 2 shows the casing of FIG. 1 in a position of use;

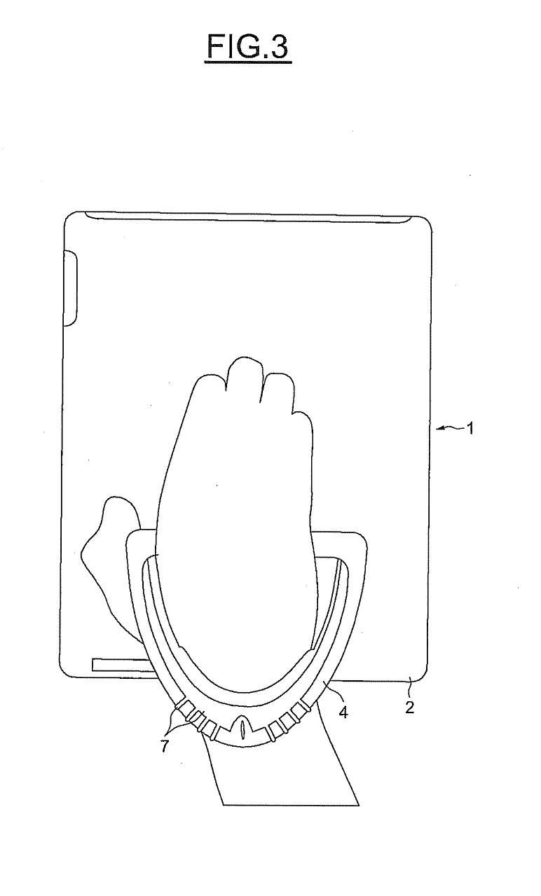

FIG. 3 shows the casing of FIG. 1 in another position of use;

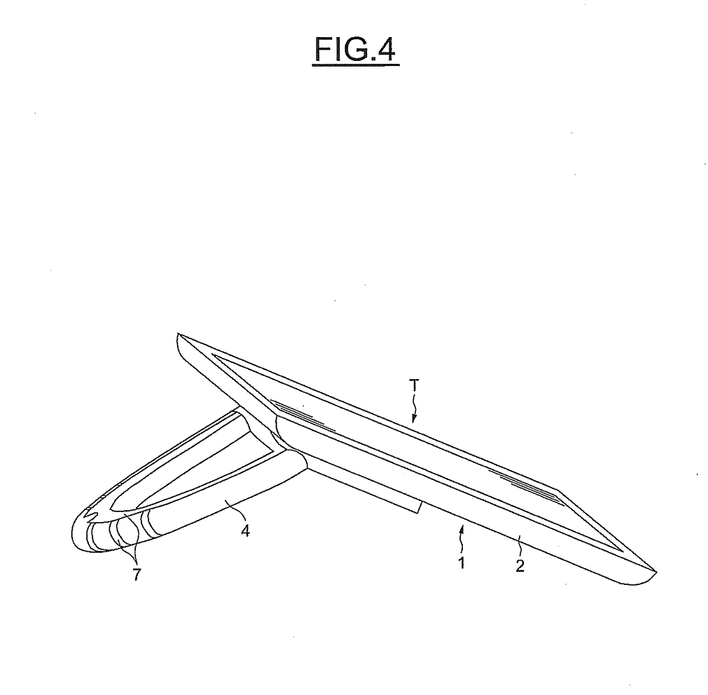

FIG. 4 shows the casing of FIG. 1 resting on the handle forming a stand;

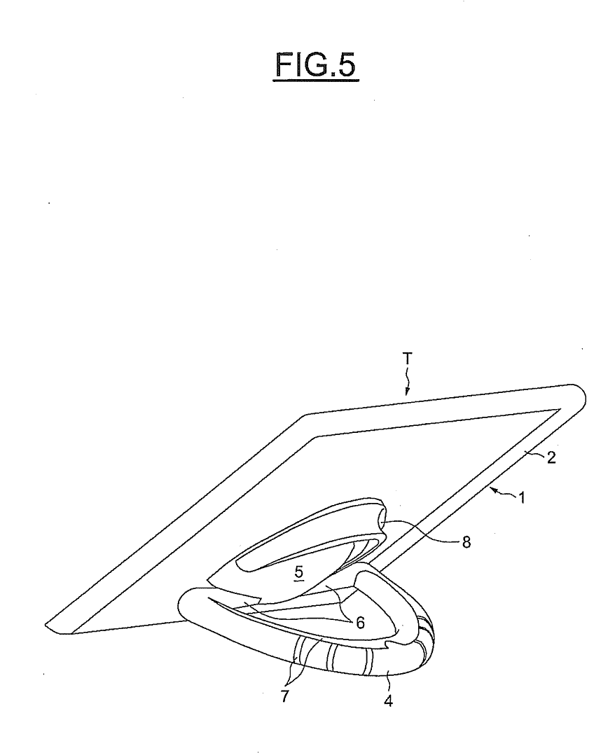

FIG. 5 illustrates another example of use of the casing of FIG. 1;

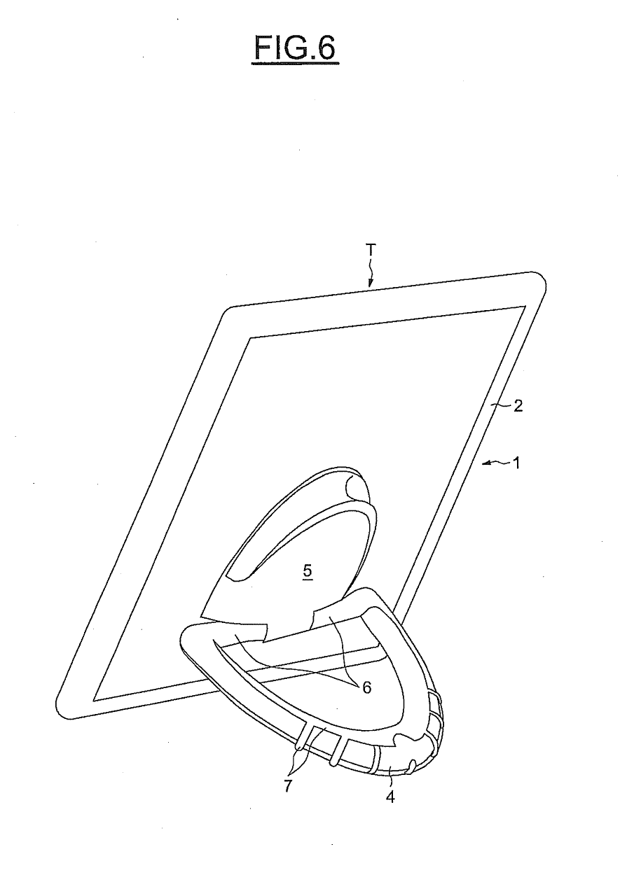

FIG. 6 is a variant of use of the casing of FIG. 1;

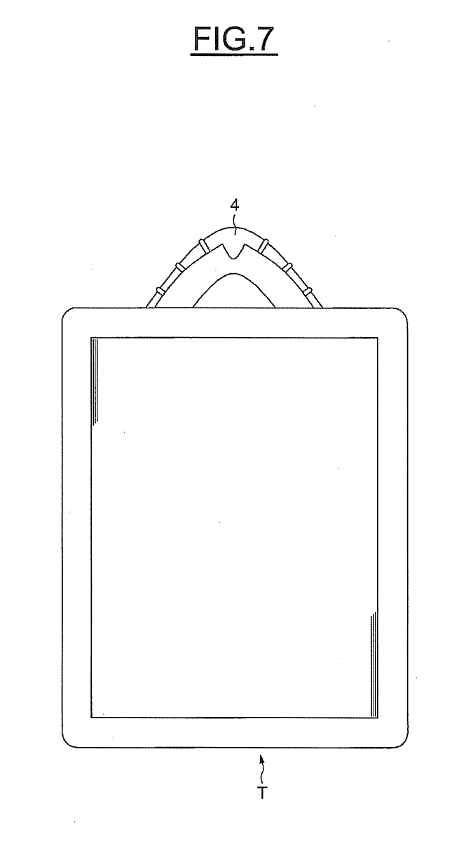

FIG. 7 illustrates yet another mode of use of the casing of FIG. 1; and

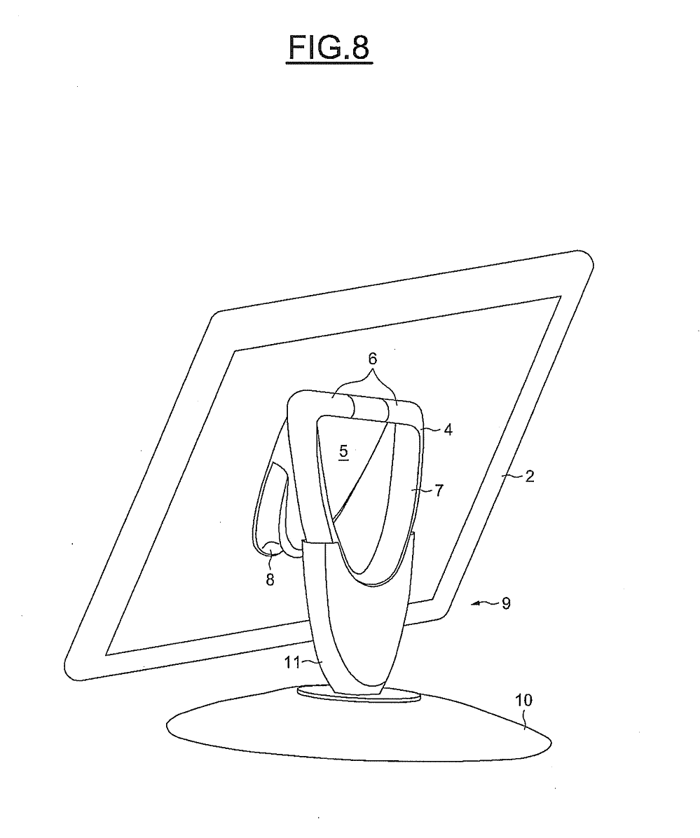

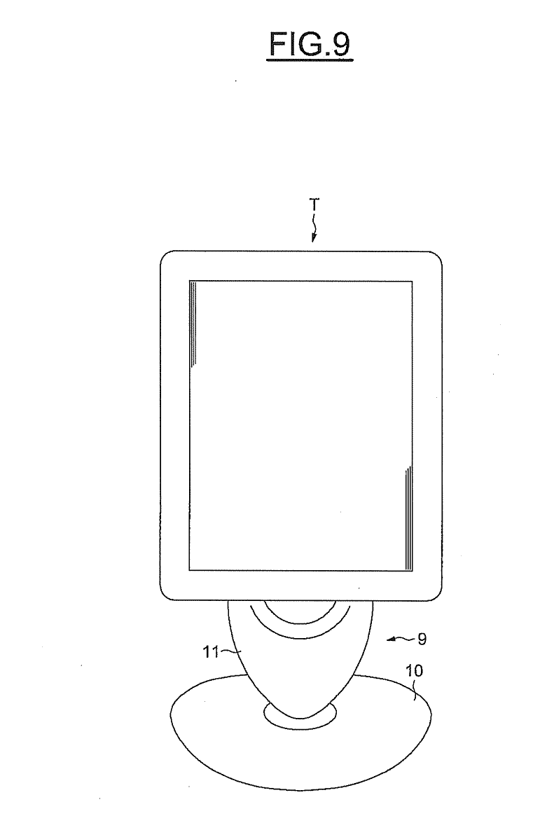

FIGS. 8 and 9 show the protective casing mounted on a base.

FIG. 1 shows a protective casing of a tablet computer indicated by the general reference number 1.

Although in the exemplary embodiment shown this casing is designed to accommodate a tablet computer T, it will be noted that there is no departure from the context of the invention when such a casing is designed to accommodate any other type of portable electronic apparatus, of the mobile telephone, digital walkman, geolocation apparatus, personal digital assistant (PDA), games console type, etc. and notably items of portable apparatus of which the dimensions do not allow them to be easily held in one hand.

As can be seen, the casing 1 essentially comprises a shell 2 comprising in this instance a rear face 3 essentially closed while being provided with a set of apertures allowing access to functional elements of the tablet and an open opposite face making the screen of the tablet accessible.

The shell 2 is preferably made of a rigid material, for example of plastic or of metal such as aluminium in order to provide effective protection for the tablet against impacts or scratches.

As can be seen in FIGS. 1 to 3, the casing 1 is moreover furnished with a handle 4 articulated on a support 5 fitted to the shell 2.

The handle 4 in this instance is generally arch-shaped, that is to say a truncated ellipse, and is provided with two mounts such as 6 allowing its articulation on the support 5.

For example, the handle 4 is made from the same material as the shell 2 but can be furnished with inserts, such as 7, made of non-slip material, for example of rubber, in order to improve the grip or the comfort of the handle or to allow, as will be described in detail below, the casing to rest on the handle 4 without risk of slippage.

As is also visible in FIGS. 1 and 2, the handle 4 is articulated on the shell 2 and is capable of adopting a first position, which can be seen in FIG. 1, in which it is flattened against the rear face 3, and a deployed position, which can be seen in FIGS. 2 and 3, in which the hand of a user can be inserted into the passageway delimited by the handle 4 in order to allow an easy grip with one hand of the tablet placed in the shell 2.

Specifically, in this position, the tablet can be firmly held by the user who can then manipulate the tablet with his free hand.

It will be noted that the support 5 is mounted so as to pivot about a pivot axis 7 so that the handle 4 can be oriented in various angular positions, over an angular range of 360°, so as to be able to use the tablet in various orientations.

Moreover, by virtue of the pivoting mount of the support, the handle can be used both by a right-handed person and by a left-handed person.

With reference to FIGS. 4 to 6, the handle 4 also forms, in the deployed position, a stand on which the tablet computer can rest, the inserts made of non-slip material preventing the tablet from slipping when it is operated.

In this case, both hands of the user are free.

As shown in FIGS. 5 and 6, by changing the angle of deployment of the handle or its direction of use, it is possible to lay down the tablet computer resting on the abutment in various positions, either horizontally or vertically.

It will be noted, furthermore, that the handle has a length such that, in the fully deployed position, it extends beyond the periphery of the shell 2, so that the handle then forms a support allowing the tablet to be hung on a hook for example attached to a wall.

As shown in FIG. 5, the support 5 is furnished with a peripheral recess 8 which is advantageously covered with a non-slip material, for example rubber, in which the handle is inserted in the folded-back position in order to prevent any risk of unintended deployment of the handle, in particular when it is being carried.

With reference finally to FIG. 8, it can be seen that the protective casing is associated with a base 9 comprising a pedestal 10 the surface of which is sufficiently large to provide good stability to the support and from which rises a housing 11 for accommodating the handle.

Therefore, in the slightly deployed position, the handle can be housed in the housing 11 and the tablet can be held in a substantially inclined position of use. Moreover, by virtue of the pivoting mounting of the support 5 on the shell 2, it is possible to orient the shell 2, and consequently the tablet, in various positions while it is held in the position of use in the base 9 (FIG. 9).

It will be finally noted that the articulation of the handle 4 on the support 5 and the mounting of the support 5 on the shell would advantageously be carried out by providing a tight assembly of the mounts 6 in the support 5 and of the support 5 on the shell or, in other words, an assembly that provides sufficient strength to allow the handle and the support to be held in the chosen position by the user despite the weight applied by the tablet.

1. Casing for protecting a portable electronic apparatus, of the tablet computer type, comprising a shell (2) delimiting a housing for accommodating the electronic apparatus, characterized in that it comprises a handle (4) articulated on the rear face of the shell (2) between a folded-back position in which it is flattened against the shell and an active deployed position allowing the casing to be held.

2. Device according to claim 1, characterized in that the handle is arch-shaped.

3. Device according to one of claims 1 and 2, characterized in that the length of the handle is such that, in the fully deployed position, it extends beyond the perimeter of the shell.

4. Device according to any one of claims 1 to 3, characterized in that the handle (4) comprises inserts (7) made of non-slip material.

5. Device according to any one of claims 1 to 4, characterized in that the handle is mounted on a pivoting support (5).

6. Device according to claim 5, characterized in that the support comprises a recess for retaining the handle in the folded-back position.

7. Device according to any one of claims 1 to 6, characterized in that the handle constitutes a stand capable of supporting the apparatus in an inclined position of use.

8. Device according to any one of claims 1 to 7, characterized in that it also comprises a base (9) provided with a pedestal (10) and with a housing (11) for accommodating the deployed handle.
